(19) United States
(12) Patent Application Publication
(10) Pub. No.: US 2009/0323295 A1
(43) Pub. Date: Dec. 31, 2009

(54) INJECTION MOLDED METAL STIFFENER AND INTEGRATED CARRIER FOR PACKAGING APPLICATIONS

(76) Inventors: Sabina J. Houle, Poenix, AZ (US); John W. Rudolph, Phoenix, AZ (US)

Correspondence Address: INTEL CORPORATION;c/o CPA Global, P.O. BOX 52050, MINNEAPOLIS, MN, 55402, US

(21) Appl. No.: 12/165,385

(22) Filed: Jun. 30, 2008

(51) Int. Cl. H05K 7/00

(52) U.S. Cl. 361/748

(57) ABSTRACT

In some embodiments, an injection molded metal stiffener and integrated carrier for packaging applications is presented. In this regard, an apparatus is introduced comprising a microelectronic device package substrate, a microelectronic device coupled with a top surface of the package substrate, and an injection-molded, metal stiffener coupled with the package substrate, wherein the stiffener includes a central opening and at least partially surrounds the microelectronic device, and wherein the stiffener includes an overhang that extends along a side of the package substrate and incorporates a coupling feature. Other embodiments are also disclosed and claimed.

### FIELD OF THE INVENTION

Embodiments of the present invention generally relate to the field of integrated circuit package design and, more particularly, to an injection molded metal stiffener and integrated carrier for packaging applications.

### BACKGROUND OF THE INVENTION

As microelectronic components shrink in size, a trend has emerged to provide package substrates that may be characterized as thin core substrates (that is, substrates having a core with a thickness less than or equal to 400 microns and larger than zero), or no-core substrates (that is, substrates without cores).

Disadvantageously, with a thin or no-core substrate, however, decrease in yield at first level chip attach due to warpage causing nonwets may occur during the package manufacturing process, such as, for example, during flip chip bonding where substrate flatness and rigidity are required. To address the above issue, the prior art sometimes provides substrates that may have a thickness of at least several tens of microns or more. However, the above measure disadvantageously detracts from further package size minimization.

### BRIEF DESCRIPTION OF THE DRAWINGS

The present invention is illustrated by way of example and not limitation in the figures of the accompanying drawings in which like references indicate similar elements, and in which:

FIG. 1 is a graphical illustration of a cross-sectional view of an example microelectronic device package including an injection molded metal stiffener with an attachment feature, in accordance with one example embodiment of the invention;

FIG. 2 is a graphical illustration of a cross-sectional view of an example microelectronic device package including an injection molded metal stiffener and integrated carrier, in accordance with one example embodiment of the invention;

FIG. 3 is a graphical illustration of a cross-sectional view of another example microelectronic device package including an injection molded metal stiffener with an attachment feature, in accordance with one example embodiment of the invention;

FIG. 4 is a graphical illustration of a cross-sectional view of another example microelectronic device package including an injection molded metal stiffener and integrated carrier, in accordance with one example embodiment of the invention; and

FIG. 5 is a block diagram of an example electronic appliance suitable for implementing a microelectronic device package including an injection molded metal stiffener with an attachment feature, in accordance with one example embodiment of the invention.

### DETAILED DESCRIPTION

In the following description, for purposes of explanation, numerous specific details are set forth in order to provide a thorough understanding of the invention. It will be apparent, however, to one skilled in the art that embodiments of the invention can be practiced without these specific details. In other instances, structures and devices are shown in block diagram form in order to avoid obscuring the invention,

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment. Furthermore, the particular features, structures or characteristics may be combined in any suitable manner in one or more embodiments.

FIG. 1 is a graphical illustration of a cross-sectional view of an example microelectronic device package including an injection molded metal stiffener with an attachment feature, in accordance with one example embodiment of the invention. As shown, integrated circuit package 100 includes one or more of microelectronic device 102, package substrate 104, substrate top surface 106, injection molded metal stiffener 108, stiffener overhang 110, attachment feature 111, stiffener rib 112, conductive traces 114, conductive contacts 116, stiffener top surface 118, substrate copper pad 120 and stiffener height 122.

Microelectronic device 102 is intended to represent any type of integrated circuit die. In one embodiment, microelectronic device 102 is a multi-core microprocessor. Microelectronic device 102 includes an active surface which contains the electrical connections that couple with conductive traces 114 at substrate top surface 106.

Package substrate 104 represents any type of microelectronic device package substrate. In one embodiment, package substrate 104 represents a multi-layer organic substrate. In one embodiment, conductive traces 114 conductively couple microelectronic device 102 on substrate top surface 106 through build up layers to conductive contacts 1 16. Conductive contacts 116 couple with conductive traces 114 and allow integrated circuit package 100 to be electrically coupled, for example by a socket connection, to a circuit board. In one embodiment, conductive contacts 116 include solder bumps. In another embodiment, conductive contacts 116 include lands.

Injection molded metal stiffener 108 is attached to package substrate 104 to provide stiffening, which one skilled in the art would recognize may be essential for very thin packages. The mold used to create injection molded metal stiffener 108 may include features such as stiffener overhang 110, which may be designed to extend along one or more side(s) of package substrate 104, attachment feature 111, which may be designed to couple with a carrier, and/or stiffener rib 112, which may be designed to extend vertically up from injection molded metal stiffener 108. Injection molded metal stiffener 108 may include a central opening and at least partially surrounds microelectronic device 102. Injection molded metal stiffener 108 may border all or fewer than all sides of microelectronic device 102.

In one embodiment, stiffener overhang 110 extends below conductive contacts 116 so that attachment feature 111 may couple with a backside of a carrier. While shown as an edge grip attachment feature that snaps into place, attachment feature 111 may be any feature (for example pins, tabs, or notches) to mechanically restrain integrated circuit package 100 to a carrier.

In one embodiment, injection molded metal stiffener 108 is composed substantially of magnesium. In other embodiments, injection molded metal stiffener 108 may be composed of magnesium-zinc, magnesium-aluminum, or other magnesium or aluminum or zinc alloys. In one embodiment, the metal used to mold injection molded metal stiffener 108 is chosen for thixotropic properties, such that when heated near its melting point and shear forces are applied, the metal may have viscous or plastic-like flow properties.

In one embodiment, stiffener top surface 118 is substantially flush with substrate top surface 106, though in other embodiments, stiffener top surface 118 may be extend above or below substrate top surface 106. Injection molded metal stiffener 108 may be coupled with package substrate 104 before or after or contemporaneous to microelectronic device 102 is coupled with package substrate 104. Package substrate 104 may include copper pad 120 through which injection molded metal stiffener 108 is soldered to package substrate 104. In another embodiment, a polymer adhesive is used to bond injection molded metal stiffener 108 with package substrate 104. Injection molded metal stiffener 108 may have a stiffener height 122 of a little as about 12 mils.

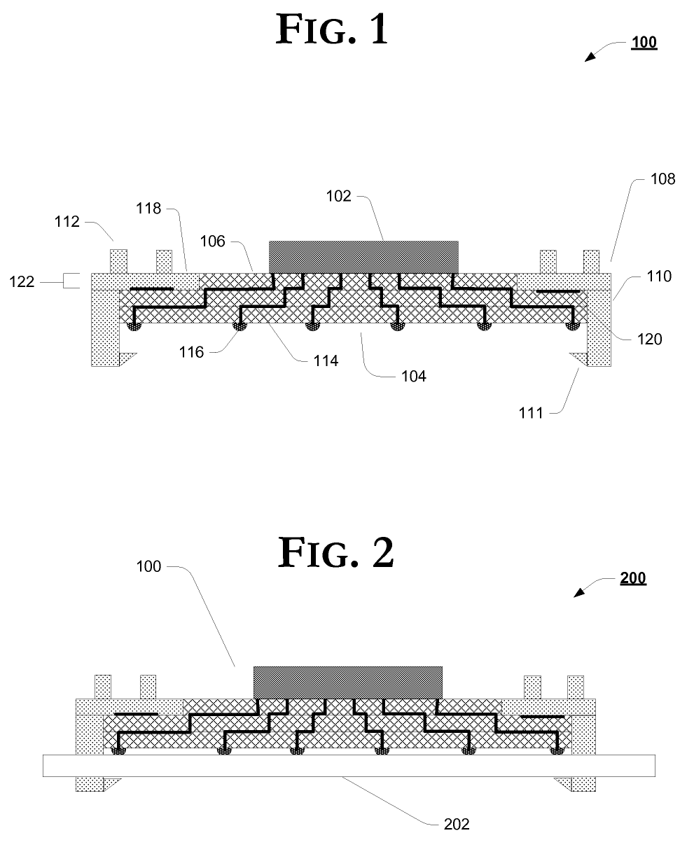

FIG. 2 is a graphical illustration of a cross-sectional view of an example microelectronic device package including an injection molded metal stiffener and integrated carrier, in accordance with one example embodiment of the invention. As shown, assembly 200 includes one or more of integrated circuit package 100 and carrier 202.

Carrier 202 may represent a circuit board, such as a motherboard, with openings to accept attachment features 111. In one embodiment, carrier 202 represents a manufacturing tray. Attachment features 111 of integrated circuit package 100 may slide or snap into place under carrier 202 mechanically holding integrated circuit package 100 in place. In one embodiment integrated circuit package 100 is held in place so that conductive contacts 116 can be reflowed to pads on top of carrier 202.

FIG. 3 is a graphical illustration of a cross-sectional view of another example microelectronic device package including an injection molded metal stiffener with an attachment feature, in accordance with one example embodiment of the invention. As shown, integrated circuit package 300 includes one or more of microelectronic device 302, package substrate 304, injection molded metal stiffener 306, stiffener overhang 308, attachment feature 309, stiffener rib 310, substrate top surface 312, and stiffener height 3 14.

Package substrate 304 may represent a bump-less build up layer substrate. In one embodiment, microelectronic device 302 and injection molded metal stiffener 306 are placed on a holding plate while encapsulation material is disposed between them forming a bond. Substrate top surface 312 may then be formed under the device and stiffener combination, followed by subsequent substrate layers. Injection molded metal stiffener 306 may include a central opening and at least partially surrounds microelectronic device 302. Injection molded metal stiffener 306 may be adjacent to all or fewer than all sides of microelectronic device 302.

In one embodiment, stiffener overhang 308 extends below integrated circuit package 300 so that attachment feature 309 may couple with a backside of a carrier. While shown as notched tab attachment feature that slides into place, attachment feature 309 may be any feature (for example pins, tabs, rivets or notches) to mechanically restrain integrated circuit package 300 to a carrier.

While shown as including stiffener rib 310, injection molded metal stiffener 308 may be formed without this feature. In one embodiment, stiffener height 314 is substantially equal to the height of microelectronic device 302.

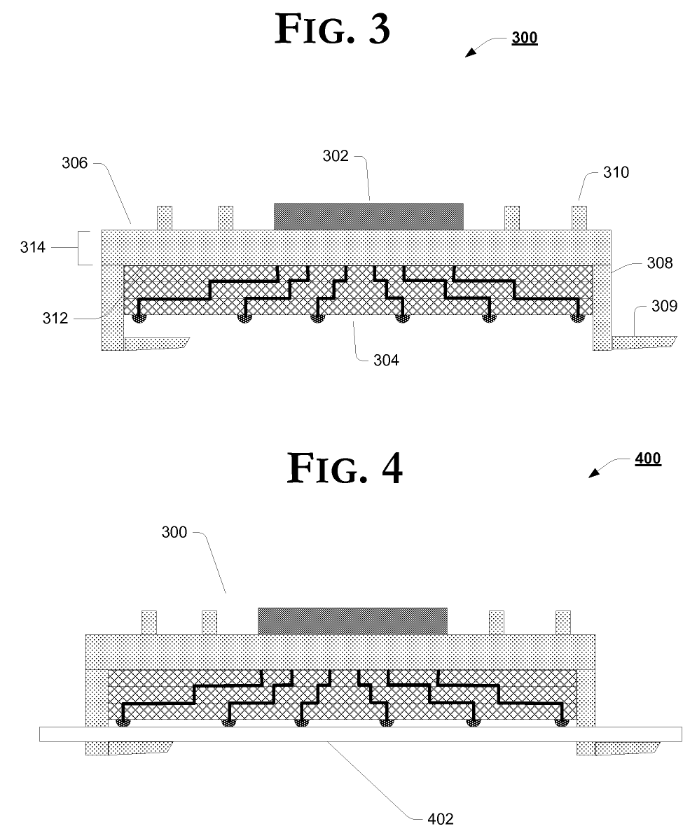

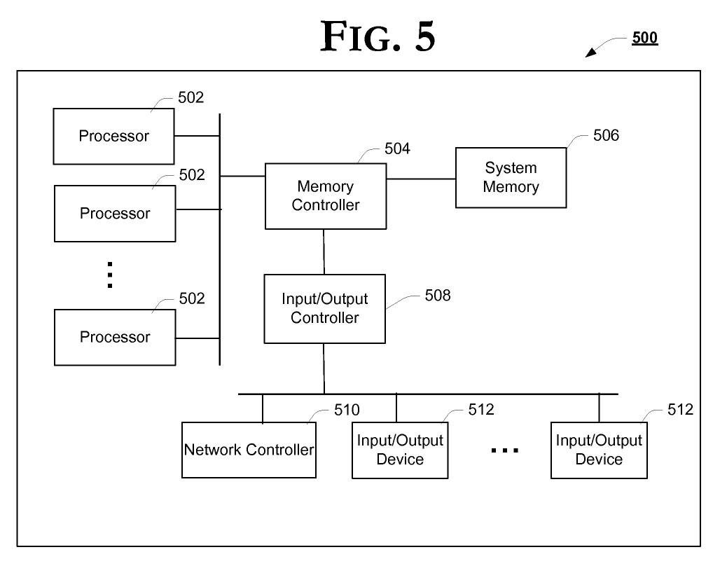

FIG. 4 is a graphical illustration of a cross-sectional view of another example microelectronic device package including an injection molded metal stiffener and integrated carrier, in accordance with one example embodiment of the invention. As shown, assembly 400 includes one or more of integrated circuit package 300 and carrier 402.

Carrier 402 may represent a circuit board, such as a motherboard, with openings to accept attachment features 309. In one embodiment, carrier 402 represents a manufacturing tray. Attachment features 309 of integrated circuit package 300 may slide or snap into place under carrier 402 mechanically holding integrated circuit package 300 in place. In one embodiment integrated circuit package 300 is held in place so that conductive contacts of integrated circuit package 300 can be reflowed to pads on top of carrier 402.

FIG. 5 is a block diagram of an example electronic appliance suitable for implementing a microelectronic device package including an injection molded metal stiffener with an attachment feature, in accordance with one example embodiment of the invention. Electronic appliance 500 is intended to represent any of a wide variety of traditional and non-traditional electronic appliances, laptops, desktops, cell phones, wireless communication subscriber units, wireless communication telephony infrastructure elements, personal digital assistants, set-top boxes, or any electric appliance that would benefit from the teachings of the present invention. In accordance with the illustrated example embodiment, electronic appliance 500 may include one or more of processor(s) 502, memory controller 504, system memory 506, input/output controller 508, network controller 510, and input/output device(s) 512 coupled as shown in FIG. 5. Processor(s) 502, or other integrated circuit components of electronic appliance 500, may comprise a microelectronic device package including an injection molded metal stiffener with an attachment feature as described previously as an embodiment of the present invention.

Processor(s) 502 may represent any of a wide variety of control logic including, but not limited to one or more of a microprocessor, a programmable logic device (PLD), programmable logic array (PLA), application specific integrated circuit (ASIC), a microcontroller, and the like, although the present invention is not limited in this respect. In one embodiment, processors(s) 502 are Intel® compatible processors. Processor(s) 502 may have an instruction set containing a plurality of machine level instructions that may be invoked, for example by an application or operating system.

Memory controller 504 may represent any type of chipset or control logic that interfaces system memory 506 with the other components of electronic appliance 500. In one embodiment, the connection between processor(s) 502 and memory controller 504 may be a point-to-point serial link. In another embodiment, memory controller 504 may be referred to as a north bridge.

System memory 506 may represent any type of memory device(s) used to store data and instructions that may have been or will be used by processor(s) 502. Typically, though the invention is not limited in this respect, system memory 506 will consist of dynamic random access memory (DRAM). In one embodiment, system memory 506 may consist of Rambus DRAM (RDRAM). In another embodiment, system memory 506 may consist of double data rate synchronous DRAM (DDRSDRAM).

Input/output (I/O) controller 508 may represent any type of chipset or control logic that interfaces I/O device(s) 512 with the other components of electronic appliance 500. In one embodiment, I/O controller 508 may be referred to as a south bridge. In another embodiment, I/O controller 508 may comply with the Peripheral Component Interconnect (PCI) Express™ Base Specification, Revision 1.0a, PCI Special Interest Group, released Apr. 15, 2003.

Network controller 510 may represent any type of device that allows electronic appliance 500 to communicate with other electronic appliances or devices. In one embodiment, network controller 510 may comply with a The Institute of Electrical and Electronics Engineers, Inc. (IEEE) 802.11b standard (approved Sep. 16, 1999, supplement to ANSI/IEEE Std 802.11, 1999 Edition). In another embodiment, network controller 510 may be an Ethernet network interface card.

Input/output (I/O) device(s) 512 may represent any type of device, peripheral or component that provides input to or processes output from electronic appliance 500.

In the description above, for the purposes of explanation, numerous specific details are set forth in order to provide a thorough understanding of the present invention. It will be apparent, however, to one skilled in the art that the present invention may be practiced without some of these specific details. In other instances, well-known structures and devices are shown in block diagram form.

Many of the methods are described in their most basic form but operations can be added to or deleted from any of the methods and information can be added or subtracted from any of the described messages without departing from the basic scope of the present invention. Any number of variations of the inventive concept is anticipated within the scope and spirit of the present invention. In this regard, the particular illustrated example embodiments are not provided to limit the invention but merely to illustrate it. Thus, the scope of the present invention is not to be determined by the specific examples provided above but only by the plain language of the following claims.

What is claimed is:

1. An apparatus comprising:
a microelectronic device package substrate, wherein the package substrate comprises a multi-layer organic substrate;
a microelectronic device coupled with a top surface of the package substrate; and
an injection-molded, metal stiffener coupled with the package substrate, wherein the stiffener includes a central opening and at least partially surrounds the microelectronic device, and wherein the stiffener includes an overhang that extends along a side of the package substrate and is designed to couple with a carrier.

2. The apparatus of claim 1, wherein the stiffener further comprises a rib that extends vertically up from the stiffener.

3. The apparatus of claim 1, wherein the stiffener comprises magnesium.

4. The apparatus of claim 1, wherein a top surface of the stiffener is substantially flush with the top surface of the package substrate.

5. The apparatus of claim 1, wherein the stiffener is soldered to a copper pad on the package substrate.

6. The apparatus of claim 1, wherein the stiffener is designed to couple with a carrier comprises a notched tab attachment feature.

7. An electronic appliance comprising:
a network controller;
a system memory; and
a processor, wherein said processor comprises:
a microelectronic device package substrate;
a microelectronic device coupled with a top surface of the package substrate; and
an injection-molded, metal stiffener coupled with the package substrate, wherein the stiffener includes a central opening and at least partially surrounds the microelectronic device, and wherein the stiffener includes an overhang that extends along a side of the package substrate and incorporates a coupling feature.

8. The electronic appliance of claim 7, wherein the coupling feature comprises an edge grip attachment feature.

9. The electronic appliance of claim 7, wherein the stiffener further comprises a rib that extends vertically up from the stiffener.

10. The electronic appliance of claim 7, wherein the stiffener comprises magnesium-zinc alloy.

11. The electronic appliance of claim 7, wherein the stiffener comprises a height of about 12 mils.

12. The electronic appliance of claim 7, wherein the stiffener comprises magnesium-aluminum alloy.

13. An apparatus comprising:
a microelectronic device package substrate, wherein the package substrate comprises a bump-less build up layer substrate;
a microelectronic device coupled with a top surface of the package substrate; and
an injection-molded, metal stiffener coupled with the package substrate, wherein the stiffener includes a central opening and at least partially surrounds the microelectronic device, and wherein the stiffener includes an overhang that extends along a side of the package substrate and is designed to couple with a circuit board.

14. The apparatus of claim 13, wherein the stiffener is designed to couple with a circuit board comprises a notched tab attachment feature.

15. The apparatus of claim 13, wherein the stiffener comprises zinc alloy.

16. The apparatus of claim 13, wherein the stiffener is in contact with the microelectronic device.

17. The apparatus of claim 13, wherein the stiffener is coupled to the package substrate through a polymer adhesive.

18. The apparatus of claim 13, wherein the stiffener is designed to couple with a circuit board comprises an edge grip attachment feature.
